(19) United States
(12) Patent Application Publication
(10) Pub. No.: US 2014/0306111 A1
(43) Pub. Date: Oct. 16, 2014

(54) Low Temperature Co-Fired Ceramic System on Package for Millimeter Wave Optical Receiver and Method of Fabrication

(71) Applicant: Telekom Malaysia Berhad, Kuala Lumpur (MY)

(72) Inventors: Sabrina Mohd Shapee, Serdang (MY); Mohd Zulfadli Mohamed Yusoff, Bandar Baru Bangi (MY); Azmi Ibrahim, Bandar Baru Bangi (MY); Rosidah Alias, Kajang (MY); Muhammad Redzuan Saad, Shah Alam (MY); Zulkifli Ambak, Kajang (MY)

(73) Assignee: Telekom Malaysia Berhad, Kuala Lumpur (MY)

(21) Appl. No.: 14/247,133

(22) Filed: Apr. 7, 2014

(30) Foreign Application Priority Data
Apr. 10, 2013 (MY) PI 2013700563

(51) Int. Cl. G01J 5/10; H01L 31/18

(52) U.S. Cl. CPC G01J 5/10; H01L 31/18
USPC 250/338.1; 438/57

(57) ABSTRACT

The present disclosure relates to a multi-layered low temperature co-fired ceramic (LTCC) system on package (SoP) for a millimeter wave optical receiver comprising a top layer, a plurality of first intermediate layers, a plurality of second intermediate layers, and a bottom layer. The top layer further comprises a matching network, passive components, and a signal line disposed on a substrate material, the plurality of first intermediate layers further comprises active amplification components, via holes and a plurality of inner grounding planes that are respectively disposed on a first plurality of LTCC substrates, the plurality of second intermediate layers further comprises a plurality of grounding planes that are respectively disposed on a second plurality of LTCC substrates; and the bottom layer further comprises a grounding plane that is disposed on the bottom surface of the second plurality of LTCC substrates. A method of fabricating the multi-layered LTCC SoP is also described.

### FIELD

The present disclosure generally relates to the field of low temperature co-fired ceramic (LTCC) system on packages (SoP) for millimeter wave optical receiver circuitry and its fabrication method, and more specifically, to an optical receiver operating at 60 GHz that is fabricated on a LTCC substrate for use within a remote antenna unit (RAU) for millimeter wave radio over fiber (RoF) applications.

### BACKGROUND ART

Radio over fiber (RoF) applications are of growing interest in the application of high data rate wireless communication. Wireless networks based on RoF technologies are promising cost-effective solutions to meet ever increasing user bandwidth and wireless demands. To merge optical and radio frequency (RF) function in one circuit environment, low temperature co-fired ceramic (LTCC) technology has shown great potential due to its ability to enable three-dimensional integration and interconnection as well as packaging of active and passive RF components up to millimeter wave frequencies.

LTCC has been proposed to be used as substrates for the fabrication of monolithic integrated circuits. The advantages of using LTCC as substrates for the fabrication of monolithic integrated circuits include a low dielectric constant and low circuit resistance. LTCC technology has become an attractive material system for innovative designs due to multilayer fabrication capabilities, low loss transmission lines, miniaturization, and high quality factor passive devices for microwave and millimeter wave circuits.

LTCC technology offers the advantage of the ability to accommodate high density modules and low circuit resistance that is achieved through the use of silver and gold as inner conductor materials. Higher reliability in structure is achieved by selecting materials with suitable thermal expansion coefficients with the mounted components, improved electromagnetic compatibility and high dielectric constant. LTCC technology can be used to integrate active components such as power amplifiers (PA), low noise amplifiers (LNA), mixers, and intermediate frequency amplifiers on top layers while having buried passive devices such as filters, matching network and antenna into a single package.

### SUMMARY

The present disclosure describes a system and method of fabricating a multi-layered low temperature co-fired ceramic (LTCC) system on package (SoP) for a millimeter wave optical receiver circuitry, wherein an optical receiver operating at 60 GHz is fabricated on an LTCC substrate for use within a remote antenna unit (RAU) for millimeter wave radio over fiber (RoF) applications.

In one aspect of the present disclosure, a multi-layered LTCC SoP for millimeter wave optical receiver comprises a top layer, a plurality of first intermediate layers, a plurality of second intermediate layers, and a bottom layer. The top layer further comprises a matching network, passive components, and a signal line disposed on a substrate material. The plurality of first intermediate layers further comprises active amplification components, via-holes, and a plurality of inner grounding planes that are respectively disposed on a first plurality of LTCC substrates. The plurality of second intermediate layers further comprises a plurality of grounding planes that are respectively disposed on a second plurality of LTCC substrates. The bottom layer further comprises a grounding plane that is disposed on the bottom surface of the second plurality of LTCC substrates.

In one embodiment of the present disclosure, the signal line comprises a single line width of 100 μm±10 μm, the passive components comprise a band pass filter (17) and a patch antenna (16), and the active amplification components (18) comprise a low noise amplifier and a power amplifier.

Another aspect of the present disclosure is a method of fabricating a multi-layered LTCC SoP for a millimeter wave optical receiver. The method comprises blanking a reel of LTCC tape to produce pieces of LTCC tape of a predetermined size, mechanically punching a plurality of via holes and filling the via holes with a conductive paste, screen printing to form a multi-layer substrate comprising a top layer, a plurality of first and second intermediate layers and a bottom layer, and collating, laminating and co-firing the multi-layer substrate to form the millimeter wave optical receiver.

In one embodiment of the present disclosure, laminating is achieved by applying a pressure of 21 MPa at a temperature of 70° C. for duration of 10 minutes, while co-firing further comprises burning out an organic binder of the LTCC multi-layer substrate at a temperature of 450° C. and thereafter burning out the ceramic material of the LTCC multi-layer substrate at a temperature of 850° C.

The present disclosure describes features and a combination of parts hereinafter fully described and illustrated in the accompanying drawings, it being understood that various changes in the details may be made without departing from the scope of the invention or sacrificing any of the advantages of the invention.

### BRIEF DESCRIPTION OF THE ACCOMPANYING DRAWINGS

To further clarify various aspects of some embodiments of the present disclosure, a more particular description will be rendered by references to specific embodiments thereof, which are illustrated in the appended drawings. It should be appreciated that these drawings depict only typical embodiments of the disclosure and are therefore not to be considered limiting of its scope. The embodiments will be described and explained with additional specificity and detail through the accompanying drawings in which:

FIG. 1 is a diagram illustrating a millimeter wave RoF system of the prior art;

FIG. 2 is a block diagram for an LTCC SoP millimeter wave optical receiver of the prior art;

FIG. 3 is a diagram illustrating a plan view of the impedance matching network for millimeter optical receiver according to the present disclosure;

FIG. 4 is a diagram illustrating a cross-section view for the LTCC SoP millimeter wave optical receiver according to the present disclosure;

FIG. 5 is a diagram illustrating a perspective plan view of the co-planar waveguide according to the present disclosure;

FIG. 6 is a diagram illustrating a perspective view of the LTCC SoP millimeter wave optical receiver according to the present disclosure; and

FIG. 7 is a diagram illustrating a method of fabricating the millimeter optical receiver module according to the present disclosure.

### DETAILED DESCRIPTION

The present disclosure relates to the field of Low Temperature co-Fired Ceramic (LTCC) system on packages (SoP) for millimeter wave optical receiver circuitry and a fabrication method. It is to be understood that limiting the description to illustrative embodiments is merely to facilitate discussion of the present disclosure and it is envisioned that those skilled in the art may devise various modifications and equivalents without departing from the scope of the appended claims.

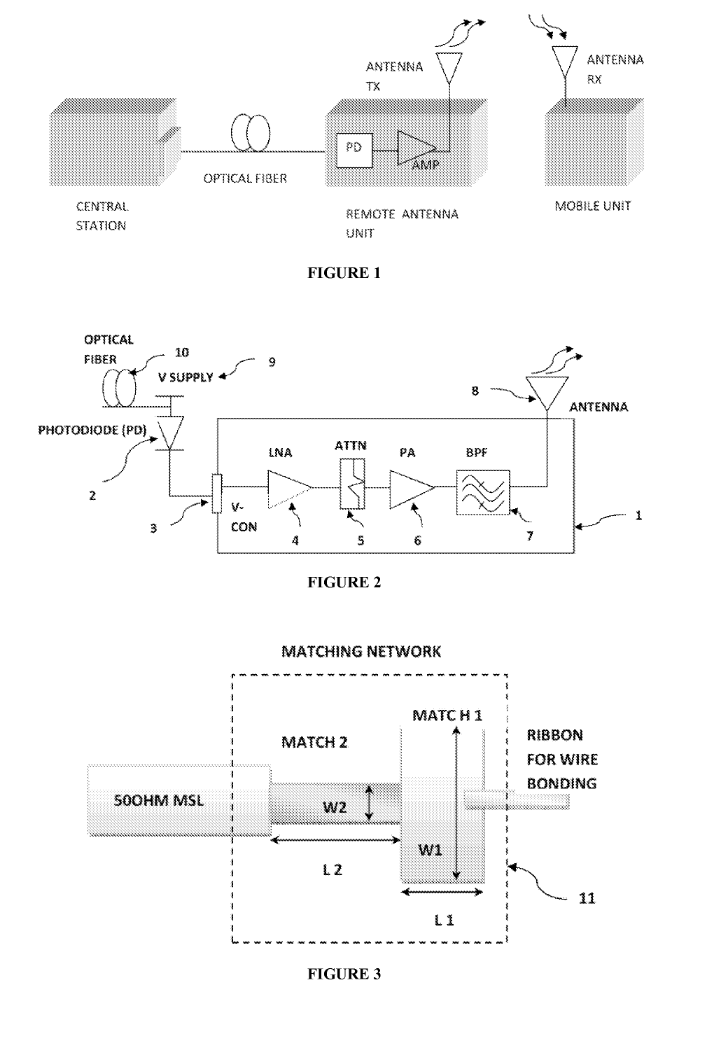

Reference is collectively made to FIGS. 1 and 2. FIG. 1 is a diagram illustrating a millimeter wave radio over fiber (RoF) system of the prior art. FIG. 2 is a block diagram for an LTCC SoP millimeter wave optical receiver of the prior art.

Based on conventional design, the millimeter wave RoF system consists of central station (CS), remote antenna unit (RAU) and Mobile Unit (MU), as shown in FIG. 1. However, the present disclosure places emphasis on LTCC SoP modules for a 60 GHz optical receiver on a remote antenna unit (RAU) for millimeter wave.

RoF approaches were designed and implemented as shown in FIG. 2. This LTCC SoP module of an optical receiver is part of the RAU downlink which consists of a photo detector (PD) as a main element to convert optical to electrical, passive elements such as an antenna (8) and band pass filter (7), and also active elements such as a Low Noise Amplifier (LNA) (4), an attenuator (5), and a power amplifier (PA) (6). The device operated in the 59-64 GHz band and is suitable for WPAN systems.

Basically, the optical receiver consists of a photo detector to receive the light signal, an amplifier to boost the weak electrical signal, and a band pass filter which is finally connected to the antenna. In order to electrically connect the LTCC SoP optical receiver modules to other circuitry, wired or ribbon leads are bonded to conductors on the top surface of the structure for connection to the other circuitry. A problem often arises with a wire bonding issue that may form a poor connection and high oscillation to the LTCC circuitry. Therefore, the impedance matching network interconnections are considered in the present disclosure for the LTCC SoP for a millimeter wave optical receiver.

Reference is now made to FIG. 3. FIG. 3 is a diagram illustrating a plan view of the impedance matching network (11) for a millimeter optical receiver according to the present disclosure. To achieve electrical signal routing in optical receiver modules, it is critical to be able to maintain impedance matching interconnections. This is done by tightly controlling the physical dimensions (L1, L2, W1, W2) of the micro-strip and strip-line transmission lines implemented within the substrate. For the present disclosure, CAD simulation was utilized to determine the matching network interconnections for LTCC SoP optical receiver modules. The impedance matching network consists of two parts (Match 1 and Match 2) as shown in FIG. 3, which are compensating the parasitic inductance due to the ribbon bonding interconnection and impedance matching network (11, 21, 23) and 50Ω MSL.

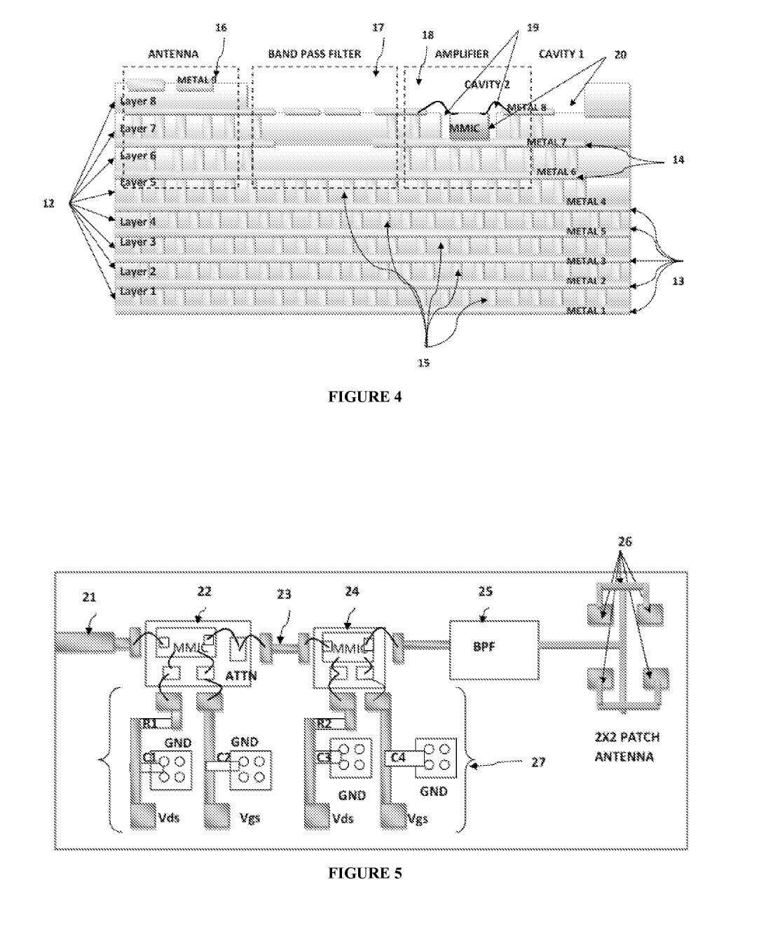

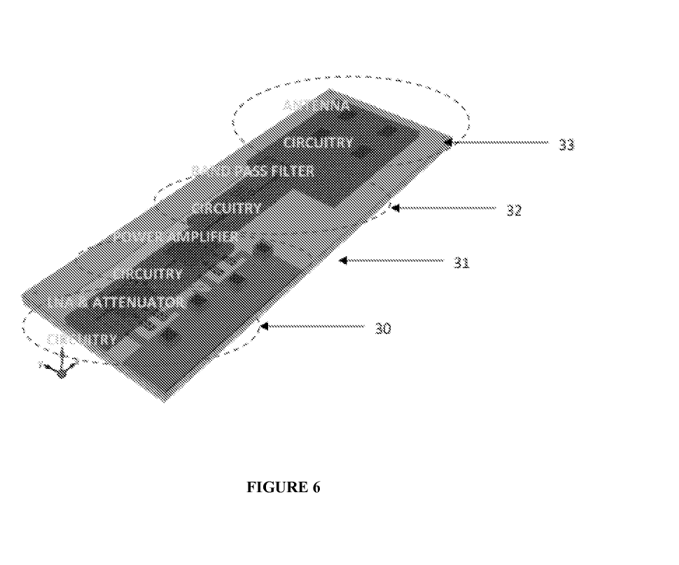

Reference is collectively made to FIGS. 4, 5 and 6. FIG. 4 is a diagram illustrating a cross-section view of the LTCC SoP millimeter wave optical receiver according to the present disclosure. FIG. 5 is a diagram illustrating a perspective plan view of the co-planar waveguide according to the present disclosure. FIG. 6 is a diagram illustrating the perspective view of the LTCC SoP millimeter wave optical receiver according to the present disclosure.

The system according to the present disclosure is a multi-layered (12) LTCC SoP for a millimeter wave optical receiver that comprises a top layer, a plurality of first intermediate layers, a plurality of second intermediate layers, and a bottom layer.

The top layer comprises a matching network, passive components such as a band pass filter (17) and a patch antenna (16), a pad for DC bias circuits, cavities, i.e., cavity 1 and cavity 2 (20), and a signal line (19) disposed on a substrate material. The signal line comprises a single line width of 100 μm±10 μm.

The plurality of first intermediate layers (layers 5 to 7) comprises active amplification components (18) such as a low noise amplifier and a power amplifier, via-holes (15), and a plurality of inner grounding planes that are respectively disposed on a first plurality of LTCC substrates. The plurality of second intermediate layers (layers 2 to 4) comprises a plurality of grounding planes that are respectively disposed on a second plurality of LTCC substrates (13, 14). The bottom layer comprises a grounding plane that is disposed on the bottom surface of the second plurality of LTCC substrates (13).

The millimeter optical receiver module according to the present disclosure does not introduce any signal amplification and is a combination of passive components (25, 26, 32, 33) and active components (22, 24, 27, 30, 31) on a single module to maximize the area of electromagnetic wave propagation and to reduce the size of the module.

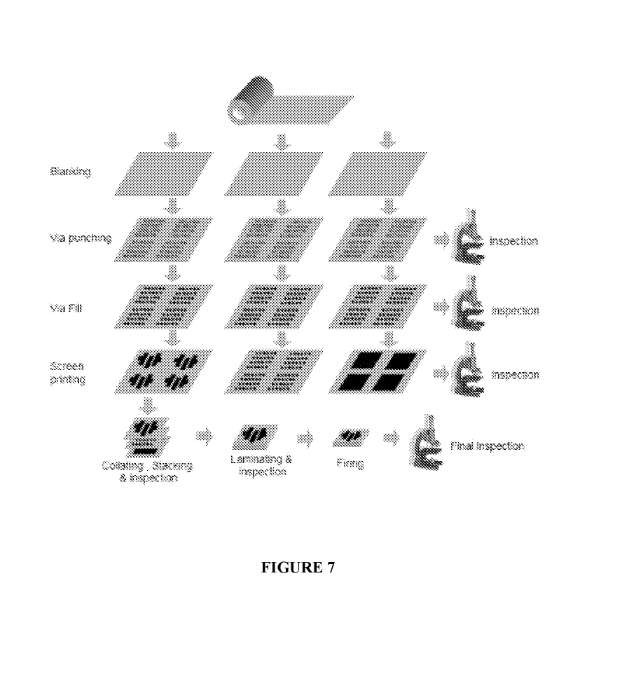

Reference is now made to FIG. 7. FIG. 7 is a diagram illustrating a method of fabricating the millimeter optical receiver module according to the present disclosure. The LTCC SoP for a millimeter wave optical receiver of the present disclosure is formed by a fabricating process that includes the process of blanking, via punching, via filling, screen printing, collating and stacking, laminating, and co-firing.

The first step of the fabrication process comprises blanking a reel of LTCC tape. The tape is blanked to produce pieces of LTCC tape of a predetermined standard size and subsequently a plurality of registration holes are made of the individual pieces of blanked tapes.

The next step of the fabrication process entails punching a plurality of via holes with the aid of a mechanical via-punching apparatus. Subsequently, the formed via holes are filled with a special purpose conductive paste.

In the following step, the conductors according to the design of the millimeter wave optical receiver which comprise the impedance matching, band pass filter, cavities and antenna of the present disclosure are deposited onto the individual LTCC tapes to thus form the top layer, the plurality of first and second intermediate layers, and the bottom layer of the present disclosure by means of screen printing.

Upon completion of the screen printing process, with the deposition of the designed conductor layout on each layer of the LTCC substrates of the millimeter optical receiver circuitry of the present disclosure, the layers are stacked and arranged according to the prescribed order dictated by the design, collated, laminated and co-fired to form the multi-layered millimeter wave optical receiver of the present disclosure.

In one embodiment of the present disclosure, the collated tapes are laminated in an isolation laminator. Typical laminating parameters depend on the material of the LTCC substrate. For Ferro A6S substrates, these parameters include a pressure of 21 MPa, temperature of 70° C. and a laminating duration of 10 minutes. The laminated tapes form the millimeter optical receiver circuitry of the present disclosure. The various layers, i.e., the top layer, the plurality of first and second intermediate layers, and the bottom layer that form the LTCC circuitry of the present disclosure upon being laminated are then co-fired to complete the fabrication of the co-planar waveguide. The first stage of co-firing comprises the burning out of an organic binder of the LTCC substrate of the various layers that make up the millimeter wave optical receiver circuitry at a temperature of 450° C. The second stage of the co-firing comprises burning out the ceramic material of the LTCC substrates of the various layers that make up the LTCC circuitry at temperatures of about 850° C. to increase its density.

1. A multi-layered low temperature co-fired ceramic (LTCC) system on package (SoP) for a millimeter wave optical receiver comprising:
a top layer;
a plurality of first intermediate layers;
a plurality of second intermediate layers; and
a bottom layer,
wherein:
the top layer further comprises a matching network, passive components, and a signal line disposed on a substrate material,
the plurality of first intermediate layers further comprises active amplification components, via holes, and a plurality of inner grounding planes that are respectively disposed on a first plurality of LTCC substrates,
the plurality of second intermediate layers further comprises a plurality of grounding planes that are respectively disposed on a second plurality of LTCC substrates, and
the bottom layer further comprises a grounding plane that is disposed on the bottom surface of the second plurality of LTCC substrates.

2. A multi-layered LTCC SoP for a millimeter wave optical receiver circuitry according to claim 1, wherein the signal line comprises a single line width of 100 μm±10 μm.

3. A multi-layered LTCC SoP for a millimeter wave optical receiver circuitry according to claim 1, wherein the passive components comprise a band pass filter and a patch antenna.

4. A multi-layered LTCC SoP for a millimeter wave optical receiver circuitry according to claim 1, wherein the active amplification components comprise a low noise amplifier and a power amplifier.

5. A method of fabricating a multi-layered low temperature co-fired ceramic (LTCC) system on package (SoP) for a millimeter wave optical receiver comprising:
blanking a reel of LTCC tape to produce pieces of LTCC tape of a predetermined size;
mechanically punching a plurality of via holes and filling the via holes with a conductive paste;
screen printing to form a multi-layer substrate comprising a top layer, a plurality of first and second intermediate layers, and a bottom layer;
collating, laminating, and co-firing the multi-layer substrate to form the millimeter wave optical receiver.

6. A method of fabricating according to claim 5, wherein laminating is achieved by applying a pressure of 21 MPa at a temperature of 70° C. for duration of 10 minutes.

7. A method of fabricating according to claim 5, wherein co-firing further comprises:
burning out an organic binder of the LTCC multi-layer substrate at a temperature of 450° C.; and
burning out the ceramic material of the LTCC multi-layer substrate at a temperature of 850° C.
